(19) United States
(12) Patent Application Publication
(10) Pub. No.: US 2018/0233423 A1
(43) Pub. Date: Aug. 16, 2018

(54) FLIP-CHIP MOUNTING OF SILICON-ON-INSULATOR DIE

(71) Applicant: SKYWORKS SOLUTIONS, INC., Woburn, MA (US)

(72) Inventors: Anthony James Lobianco, Irvine, CA (US); Hoang Mong Nguyen, Fountain Valley, CA (US); Matthew Sean Read, Foothill Ranch, CA (US); David Scott Whitefield, Andover, MA (US)

(21) Appl. No.: 15/894,053

(22) Filed: Feb. 12, 2018

Related U.S. Application Data
(60) Provisional application No. 62/458,921, filed on Feb. 14, 2017.

(51) Int. Cl. H01L 23/31; H01L 23/498; H01L 23/00

(52) U.S. Cl. CPC H01L 23/315; H01L 23/3121; H01L 23/49838; H01L 2224/16227; H01L 24/16; H01L 2924/014; H01L 2224/13144; H01L 24/13

(57) ABSTRACT

A component of an electronic device comprises a semiconductor die flip-chip mounted on a printed circuit board and a barrier mechanically coupled to a portion of the die and the printed circuit board, the barrier defining a cavity between a surface of the die and the printed circuit board.

### CROSS REFERENCE TO RELATED APPLICATIONS

This application claims priority under 35 USC § 119(e) to U.S. provisional patent application Ser. No. 62/458,921, titled “FLIP-CHIP MOUNTING OF SILICON-ON-INSULTOR DIE,” filed Feb. 14, 2017, which is incorporated by reference herein in its entirety for all purposes.

### BACKGROUND

### Field of Invention

The present invention relates generally to the mounting of semiconductor device die on mounting substrates, for example, integrated passive device substrates, laminates, or printed circuit boards. More particularly, at least some embodiments are directed to flip-chip mounting of die including silicon-on-insulator substrates on printed circuit boards.

### Discussion of Related Art

With the increasing popularity of cellular telephones and other wireless devices, demand for microchips (also referred to herein as “die”) including components operating at radio frequencies is increasing. Such microchips are often formed on silicon-on-insulator (SOI) substrates to reduce parasitic coupling of components operating at high frequencies to a thick semiconductor substrate. In some instances, such microchips are flip-chip mounted in a package that is then mounted to a printed circuit board for integration into a module or electronic device. An underfill material, for example, epoxy is provided between the microchip and material of the package. The underfill material increases the reliability and fatigue resistance of the microchip-circuit board connection by carrying a significant portion of thermal stress caused by differences in the respective coefficients of thermal expansion of the microchip and the package material.

### SUMMARY OF INVENTION

According to one aspect of the present invention there is provided a component of an electronic device. The component comprises a semiconductor die flip-chip mounted directly on a printed circuit board and a barrier mechanically coupled to a portion of the die and the printed circuit board, the barrier defining a cavity between a surface of the die and the printed circuit board.

In some embodiments, the barrier comprises a polymeric material. The barrier may comprise a thermoplastic material.

In some embodiments, the barrier comprises metal. The barrier may comprise solder.

In some embodiments, the component further comprises overmold material disposed over the die, the barrier, and a portion of the printed circuit board.

In some embodiments, the die is mounted in a cavity in the printed circuit board.

In some embodiments, the barrier is disposed about a periphery of the die.

In some embodiments, the die is electrically coupled to bonding pads disposed on the printed circuit board via one of solder bumps and gold posts. The bonding pads may be disposed within the cavity defined by the barrier.

In some embodiments, the barrier hermetically seals the cavity.

In some embodiments, the cavity is free of underfill material.

In some embodiments, the die includes radio frequency (RF) components.

In some embodiments, the die includes a silicon-on-insulator (SOI) substrate.

In some embodiments, the component is included in an electronic device module. The electronic device module may be a radio frequency (RF) device module.

In some embodiments, the component is included in an electronic device. The electronic device may be an RF device.

In accordance with another aspect, there is provided a method of forming a component of an electronic device. The method comprises forming a semiconductor die, flip-chip mounting the semiconductor die on a printed circuit board, and forming a barrier mechanically coupled to a portion of the die and the printed circuit board, the barrier defining a cavity between a surface of the die and the printed circuit board.

In some embodiments, the method further comprises mounting the component in an electronic device module.

In some embodiments, the method further comprises mounting the electronic device module in an electronic device.

### BRIEF DESCRIPTION OF DRAWINGS

Various aspects of at least one embodiment are discussed below with reference to the accompanying drawings. In the drawings, which are not intended to be drawn to scale, each identical or nearly identical component that is illustrated in various drawings is represented by a like numeral. For purposes of clarity, not every component may be labeled in every drawing. The drawings are provided for the purposes of illustration and explanation, and are not intended as a definition of the limits of the invention. In the drawings:

FIG. 1 is a cross-sectional side view of an example of a component including a semiconductor die flip-chip mounted to a printed circuit board;

FIG. 2 is a flowchart of a method of forming the component of FIG. 1;

FIG. 3 is a cross-sectional side view of another example of a component including a semiconductor die flip-chip mounted to a printed circuit board;

FIG. 4 illustrates a semiconductor wafer including a plurality of die and barrier material disposed on a surface of the wafer;

FIG. 5 is a flowchart of a method of forming the component of FIG. 3;

FIG. 6 is a cross-sectional side view of another example of a component including a semiconductor die flip-chip mounted to a printed circuit board;

FIG. 7 is a cross-sectional side view of another example of a component including a semiconductor die flip-chip mounted to a printed circuit board;

FIG. 8 is a flowchart of a method of forming the component of FIG. 6 or FIG. 7;

FIG. 9 is a block diagram of one example of a module including a semiconductor die flip-chip mounted to a printed circuit;

FIG. 10 is a block diagram of one example of a wireless device including a semiconductor die flip-chip mounted to a printed circuit board; and

FIG. 11 is a block diagram showing a more detailed representation of one example of the wireless device of FIG. 10.

### DETAILED DESCRIPTION

It has been discovered that as components of microchips are operated at higher and higher frequencies in accordance with the demands of the market for higher frequency radio frequency (RF) die, conventional underfill materials, for example, epoxies may electronically (inductively and/or capacitively) couple to the high frequency components, causing degradation in the performance of such components. Accordingly, a desire has been identified to provide for mounting of RF die, including RF die fabricated on silicon-on-insulator SOI substrates, on printed circuit boards or other laminated structures without the use of underfill material.

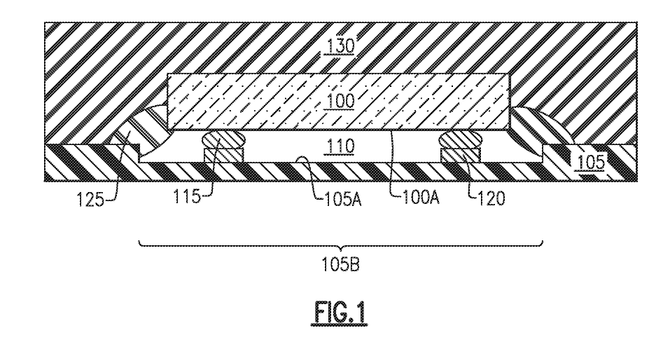

In a first example, illustrated in FIG. 1, a die 100 is directly flip-chip mounted to a printed circuit board (PCB) 105, for example, a fiberglass, laminate, or ceramic PCB. The PCB 105 may be a multi-chip module (MCM) substrate. A cavity 110 is formed between the surface 100A of the die 100 including active circuitry and an upper surface 105A of the PCB 105. The cavity 110 is substantially free or wholly free of underfill material. The cavity 110 may be defined in part by a recessed portion 105B or cavity formed in the PCB 105. The die 100 may include one or more high frequency, for example, RF components formed on a SOI substrate. The die 100 may be free of any microelectromechanical systems (MEMS) devices or movable components. The die 100 may include mounting features 115, for example, solder bumps or gold bumps or posts, that may physically and/or electrically couple the die 100 and/or circuitry within the die 100 to substrate bonding pads 120, for example, gold bond pads on the upper surface 105A of the PCB 105. The die 100 may be attached to the upper surface 105A of the PCB 105 by solder reflow, controlled collapse chip connection (C4), ultrasonic gold to gold interconnect (GGI) bonding, or other bonding methods known in the art via mounting features 115 and substrate bonding pads 120. A dam 125 (also referred to herein as a barrier) may surround and enclose the cavity 110 and prevent ingress of contaminants and/or moisture into the cavity 110. The dam 125 may contact both side and/or lower surface 100A portions of the die 100 and side and upper surfaces of the PCB 105, inside and/or outside of the cavity 110, and may be formed about an entirety of the perimeter of the die 100. The dam 125 may be formed from, for example, polyimide, epoxy, or other materials known in the art. The die 100 may be encapsulated by an overmold material 130, for example, epoxy, polyimide, or other overmold materials known in the art. The dam 125 prevents ingress of the overmold material 130 into the cavity 110. Embodiments of the dam 125 and the various embodiments of the dam or barrier described below may be disposed about a periphery of the die 100.

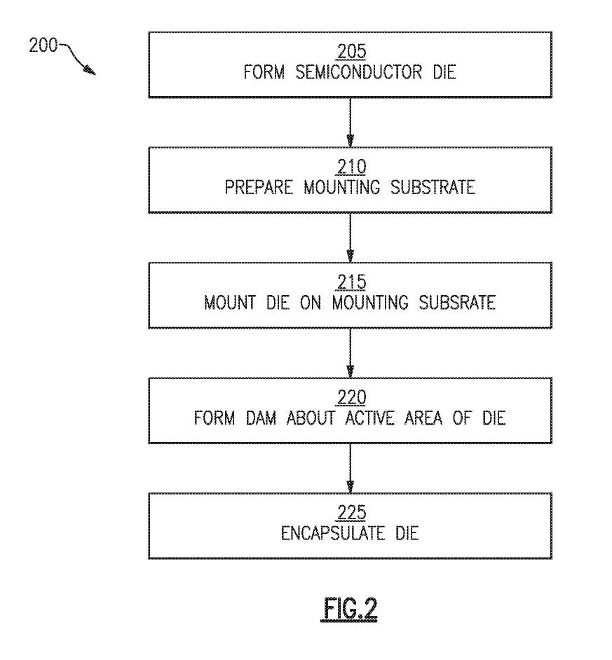

A method of mounting the die as illustrated in FIG. 1 is described with reference to the flowchart illustrated in FIG. 2, indicated generally at 200. In act 205 the semiconductor die 100 is fabricated. The semiconductor die 100 may be fabricated using known semiconductor device fabrication techniques. The semiconductor die 100 may be fabricated on a SOI substrate. The semiconductor die 100 may include one or more RF components. Fabricating the semiconductor die 100 may include forming the mounting features 115 on connection pads on the surface 100A of the die 100. In act 210 a mounting substrate, for example, PCB 105 is prepared. Preparing the substrate may include forming the recessed portion 105B or cavity in the surface 105A of the PCB 105. Preparing the substrate may include forming the substrate bonding pads 120 on the surface 105A of the PCB 105. In addition to the substrate bonding pads 120, conductive traces, and/or vias to connect various components (not shown but to be disposed on or in the PCB 105) to one another and to external devices, inputs, and/or outputs may also be formed on the PCB 105 in act 210.

In act 215, the die 100 is mounted on the mounting substrate (e.g., PCB 105). Mounting the die 100 on the PCB 105 may include mechanically and electrically coupling the mounting features 115 on the die 100 to respective substrate bonding pads 120 on the PCB 105. Mechanically and electrically coupling the mounting features 115 on the die 100 to respective substrate bonding pads 120 on the PCB 105 may be performed by, for example, solder reflow, C4 bonding, GGI bonding, or other bonding techniques known in the art.

In act 220 a dam 125 is formed about the die 100. The dam 125 may be disposed on portions of the lower surface 100A and/or side surfaces of the die 100. The dam 125 may surround active areas on the die 100. The dam 125, along with the surface 105A of the PCB 105 and surface 100A of the die, may define the cavity 110. The dam 125 may completely surround the active areas of the die 100. The dam 125 may be formed from, for example, polyimide, epoxy, or other materials known in the art. The dam 125 may be allowed to cure before proceeding further. In act 225 overmold material 130 is deposited over the die 100, PCB 105 and dam 125 to encapsulate the die 100. The dam 125 prevents the overmold material 130 from entering the cavity 110.

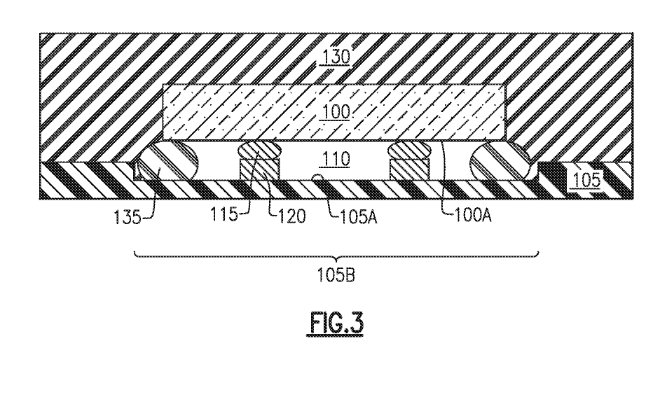

Another example of attaching a die to a mounting substrate is illustrated in FIG. 3. The example illustrated in FIG. 3 is substantially similar to that illustrated in FIG. 1, except a different form of dam 135 is utilized instead of dam 125. Dam 135 differs from dam 125 in that dam 135 is deposited on surface 100A of the die or surface 105A of the PCB 105 prior to joining the die 100 and substrate 105. Dam 135 may be formed from a gasket material that may be left uncured or partially cured prior to joining the die 100 and substrate 105. Dam 135 may be formed from similar materials as dam 125 or may be formed from a thermoplastic material, for example, poly(methyl methacrylate) (PMMA), acrylonitrile butadiene styrene (ABS), polyamide, polylactic acid (polylactide), polycarbonate (PC), polyether sulfone (PES), polyether ether ketone (PEEK), polyetherimide (PEI), polyethylene (PE), polyphenylene oxide (PPO), polyphenylene sulfide (PPS), polypropylene (PP), polystyrene (PS), polyvinyl chloride (PVC), polytetrafluoroethylene (PTFE), or other thermoplastic materials known in the art.

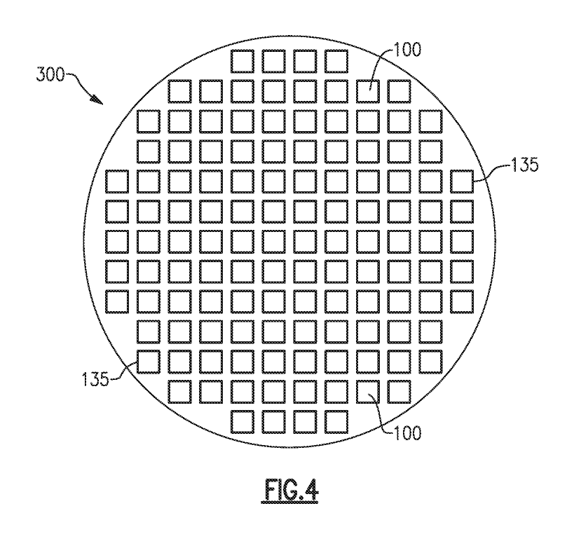

In some embodiments, the dam 135 may be disposed entirely beneath die 100 and/or entirely within recess or cavity 105B. In some embodiments, a first portion of dam 135 may be formed on the surface 100A of the die and a second portion of the dam 135 may be formed on the surface 105A of the PCB 105 prior to joining the die 100 and PCB 105. In embodiments in which the dam 135 is formed of a thermoplastic material, the material of the dam 135 or portions of the dam 135 may soften during joining of the die 100 and PCB 105, for example, due to the application of heat in a process of joining the mounting features 115 (e.g., solder balls or gold posts) on connection pads on the surface 100A of the die 100 to the substrate bonding pads 120 on the PCB 105 or application of heat from another source. The material of the dam 135 or portions of the dam 135 may then harden or be cured to form a hermetic or at least partially or nearly hermetic seal about cavity 110. In embodiments in which the material of the dam 135 is uncured or partially cured prior to joining the die 100 and PCB 105, the material of the dam may be cured upon or after joining the die 100 and PCB 105, for example, by the application of heat in a process of joining the mounting features 115 (e.g., solder balls or gold posts) on connection pads on the surface 100A of the die 100 to the substrate bonding pads 120 on the PCB 105, or application of other forms of energy or chemicals. In some embodiments, as illustrated in FIG. 4, material for forming the dam 135 may be deposited on a wafer 300 around active portions of die 100 on the wafer prior to dicing the die 100 from the wafer 300.

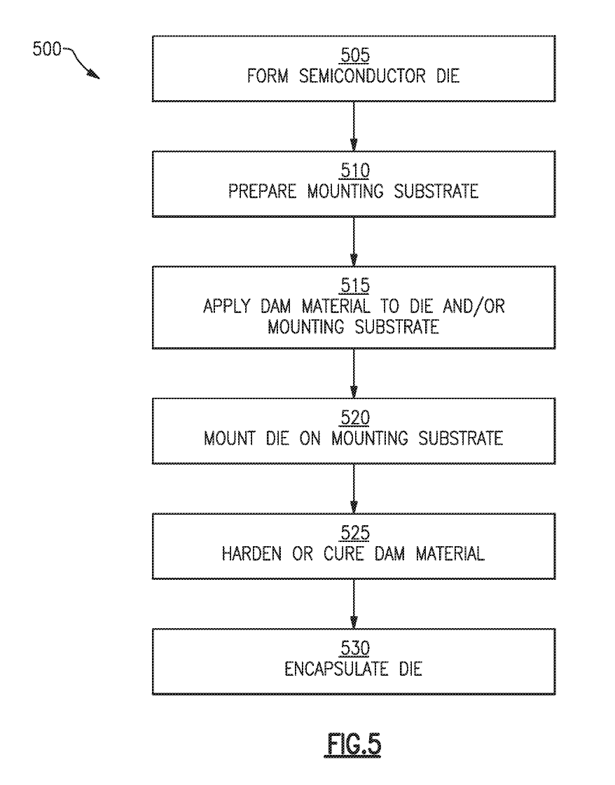

A method of mounting the die as illustrated in FIG. 3 is described with reference to the flowchart illustrated in FIG. 5, indicated generally at 500. In act 505 the semiconductor die 100 is fabricated. The semiconductor die 100 may be fabricated using known semiconductor device fabrication techniques. The semiconductor die 100 may be fabricated on a SOI substrate and may include one or more RF components. Fabricating the semiconductor die 100 may include forming the mounting features 115 on connection pads (not shown) on the surface 100A of the die 100. In act 510 a mounting substrate, for example, PCB 105 is prepared. Preparing the substrate may include forming the recessed portion 105B or cavity in the surface 105A of the PCB 105. Preparing the substrate may include forming the substrate bonding pads 120 on the surface 105A of the PCB 105. In addition to the substrate bonding pads 120, conductive traces to connect various components (not shown but to be disposed on the PCB 105) to one another and to external devices, inputs, and/or outputs may also be formed on the PCB 105 in act 510.

In act 515 material that will form the dam 135 is deposited on the surface 100A of the die 100, the surface 105A of the PCB 105, or both. In some embodiments, the material that will form the dam 135 is deposited on the surface 100A of the die 100 prior to dicing the die 100 from a wafer 300 upon which it is formed. The material that will form the dam 135 may be a thermoplastic material or a material that undergoes curing upon the application of heat or other energy, for example, ultraviolet light, or curing chemicals. After the material is deposited on the surface 100A of the die 100, the surface 105A of the PCB 105, or both, it may be partially cured to facilitate handling of the die 100 and/or PCB 105 without the material smearing, smudging, or being distorted.

In act 520, the die 100 is mounted on the mounting substrate (e.g., PCB 105). Mounting the die 100 on the PCB 105 may include mechanically and electrically coupling the mounting features 115 on the die 100 to respective substrate bonding pads 120 on the PCB 105. Mechanically and electrically coupling the mounting features 115 on the die 100 to respective substrate bonding pads 120 on the PCB 105 may be performed by, for example, solder reflow, C4 bonding, GGI bonding, or other bonding techniques known in the art.

In act 525 the material of the dam 135 is cured or hardened, for example, by the application of heat or other energy, for example, ultraviolet light, or curing chemicals. In embodiments in which the material of the dam 135 is disposed on portions of the lower surface 100A die 100 and the surface 105A of the PCB 105, the material on the lower surface 100A die 100 and the surface 105A of the PCB 105 may be joined together to form a single dam 135 in act 525. The dam 135 may surround active areas on the die 100. The dam 135 along with the surface 105A of the PCB 105 and surface 100A of the die may define the cavity 110. The dam 135 may completely surround the active areas of the die 100. In act 530 overmold material 130 is deposited over the die 100, PCB 105 and dam 135 to encapsulate the die 100. The dam 135 prevents the overmold material 130 from entering the cavity 110.

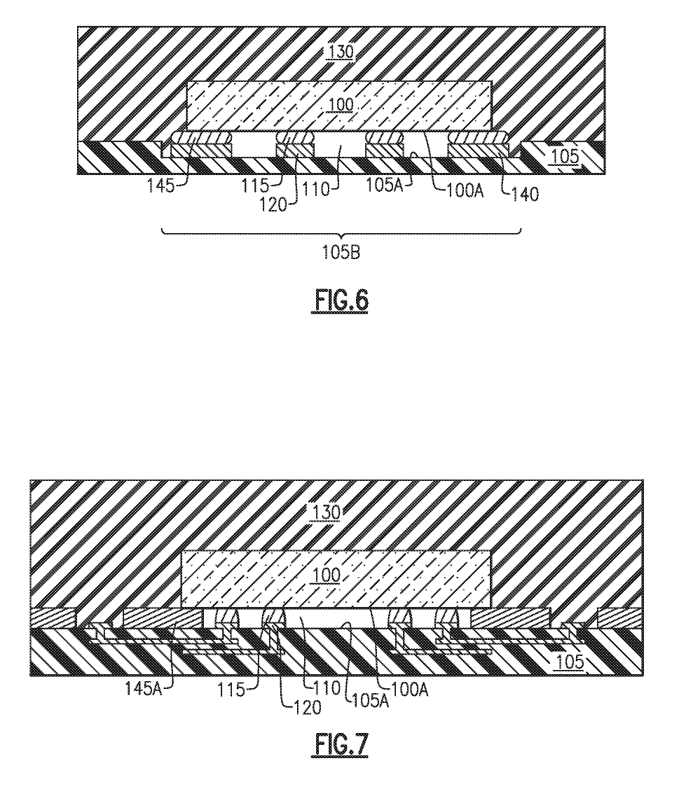

Another example of attaching a die to a mounting substrate is illustrated in FIG. 6. In the embodiment illustrated in FIG. 6, a barrier preventing the ingress of material into the cavity 110 defined between the surface 100A of the die 100 and the surface 105A of the PCB 105 includes a track of solder 145 bonded to a track of bond pad material 140 disposed on the surface 105A of the PCB 105. As used herein the term “track” refers to a layer of material formed in a closed geometric shape, for example, a circle or a rectangle. The barrier 140, 145 completely surrounds the cavity 110 and forms a seal about the cavity 110. The barrier 140, 145 prevents overmold material 130 from entering the cavity. In some embodiments, the barrier 140, 145 may be disposed entirely beneath die 100 and/or entirely within the recess or cavity 105B. In some embodiments the solder forming the track 145 may be formed of the same or similar material as the solder balls 115 and the bond pad material forming the track 140 may be formed of the same or similar material as the substrate bonding pads 120. In some embodiments, the barrier 140, 145 may provide an electrical connection (e.g., to ground or to power) to components of the die 100 in addition to the solder balls 115 and substrate bonding pads 120. The track of solder 145 may be deposited on the surface 100A of die 100 concurrently with the solder balls 115. The track of bond pad material 140 may be deposited on the surface 105A of the PCB 105 concurrently with the substrate bonding pads 120. The track of solder 145 may be bonded to the track of bond pad material 140 during the same process step used to join the solder balls 115 to the substrate bonding pads 120, for example, during a solder reflow or C4 bonding process.

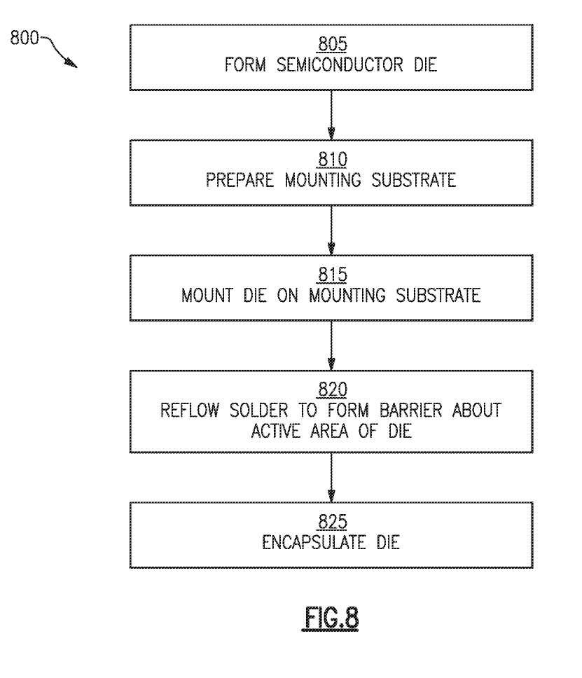

In a modification to the embodiment illustrated in FIG. 6, and as illustrated in FIG. 7, the track of solder 145 may be replaced by a portion of a solder mask 145A that extends from below the die 100 to a position outside the periphery of the die 100. During bonding of the die 100 to the surface 105A of the PCB 105, reflow of the solder balls 115 may help pull the die 100 close to the surface of the solder mask 145A, creating a sealed cavity and also creating a good electrical connection between the die 100, the solder balls 115, and the substrate bonding pads 120. FIG. 7 further illustrates that the PCB 105 need not include the recess or cavity 105B and that conductive traces in electrical contact with the substrate bonding pads 120 may be formed within the bulk of the PCB 105.

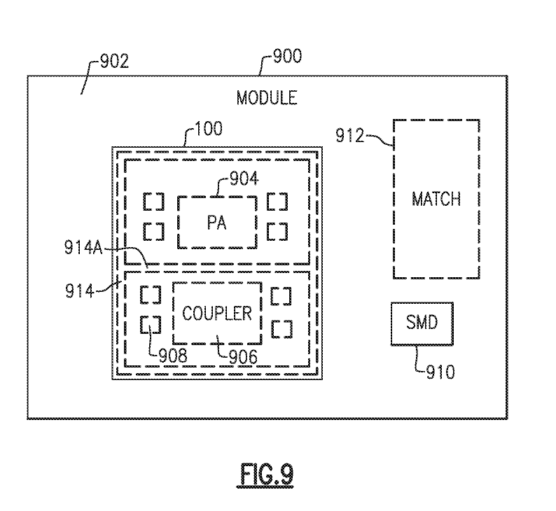

A method of mounting the die as illustrated in FIG. 6 or FIG. 7 is described with reference to the flowchart illustrated in FIG. 8, indicated generally at 800. In act 805 the semiconductor die 100 is fabricated. The semiconductor die 100 may be fabricated using known semiconductor device fabrication techniques. The semiconductor die 100 may be fabricated on a SOI substrate and may include one or more RF components. Fabricating the semiconductor die 100 may include forming the mounting features 115 on connection pads (not shown) on the surface 100A of the die 100. Fabricating the semiconductor die 100 may include forming the track of solder 145 on the surface 100A of the die 100 around active areas of the die. In some embodiments, the track of solder 145 is formed on and in electrical connection with an electrical contact on the die 100, for example, a power or ground contact. In act 810 a mounting substrate, for example, PCB 105 is prepared. Preparing the substrate may include forming the recessed portion 105B or cavity in the surface 105A of the PCB 105. Preparing the substrate may include forming the substrate bonding pads 120 on the surface 105A of the PCB 105. Preparing the substrate may include forming the track of bond pad material 140 on the surface 105A of the PCB 105. Forming the track of bond pad material 140 on the surface 105A of the PCB 105 is an optional act and need not be performed when fabricating the mounted die structure illustrated in FIG. 7. Rather, when fabricating the mounted die structure illustrated in FIG. 7, the solder mask 145A may be deposited on the surface 105A of the PCB 105. In addition to the substrate bonding pads 120 and the track of bond pad material 140, conductive traces to connect various components (not shown but to be disposed on the PCB 105) to one another and to external devices, inputs, and/or outputs may also be formed on the PCB 105 in act 810.

In act 815, the die 100 is mounted on the mounting substrate (e.g., PCB 105). Mounting the die 100 on the PCB 105 may include mechanically and electrically coupling the solder balls 115 on the die 100 to respective substrate bonding pads 120 on the PCB 105. In a process of fabricating the mounted die structure illustrated in FIG. 6, mounting the die 100 on the PCB 105 may include mechanically and, optionally, electrically coupling the track of solder 145 on the die 100 to track of bond pad material 140 on the PCB 105. In a process of fabricating the mounted die structure illustrated in FIG. 7, mounting the die 100 on the PCB 105 may include mechanically coupling the track of solder 145 on the die 100 directly to the surface 105A of the PCB 105 or mechanically coupling the solder mask 145A on the surface 105A of the PCB 105 to the die 100. Mechanically and electrically coupling the solder balls 115 on the die 100 to respective substrate bonding pads 120 on the PCB 105 and coupling the track of solder 145 on the die 100 to track of bond pad material 140 on the PCB 105 may be performed by, for example, solder reflow, C4 bonding, or other bonding techniques known in the art.

In act 820 a solder reflow act may be performed to ensure that the track of solder 145 is well bonded, and optionally electrically coupled, to the track of bonding material 140 or to the surface 105A of the PCB 105 and that the solder balls 115 are well bonded and electrically coupled to the substrate bonding pads 120. The barrier formed from the track of solder 145, the portion of a solder mask 145A, or the track of solder 145 in combination with the track of bonding material 140 may surround active areas on the die 100. The barrier, along with the surface 105A of the PCB 105 and surface 100A of the die, may define the cavity 110. The barrier may completely surround the active areas of the die 100. In act 825 overmold material 130 is deposited over the die 100, PCB 105 and the barrier formed from the track of solder 145, the portion of a solder mask 145A, or the track of solder 145 in combination with the track of bonding material 140 to encapsulate the die 100. The barrier prevents the overmold material 130 from entering the cavity 110.

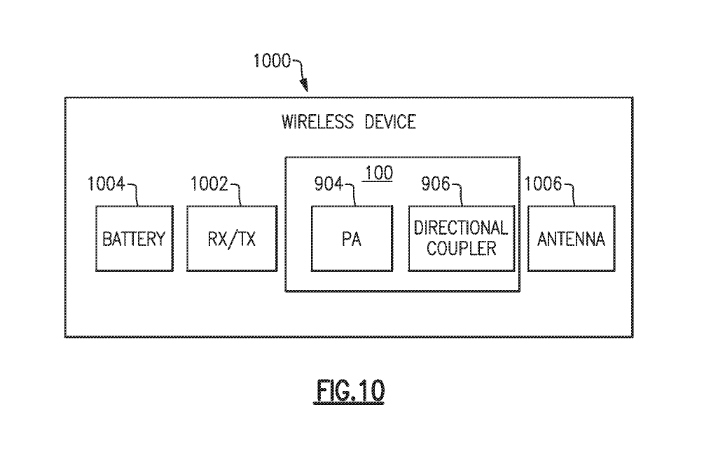

Embodiments described herein can be implemented in a variety of different modules including, for example, a front-end module, an impedance matching module, an antenna tuning module, an antenna switch module, or the like. FIG. 9 illustrates one example of a module 900 that can include any of the embodiments or examples of the flip-chip mounted die 100 disclosed herein. Overmold material 130 is omitted from FIG. 9 for clarity. Module 900 has a packaging substrate 902 that is configured to receive a plurality of components including one or more embodiments or examples of a flip-chip mounted die 100 as disclosed herein. Packaging substrate 902 may be, for example, PCB 105. In some embodiments, the die 100 can include a power amplifier (PA) circuit 904 and a coupler 906, or other RF components or circuitry known in the art, for example, a switch, or filter. A plurality of connection pads 908, for example, solder or gold bumps or posts 115 can facilitate electrical connections to connection pads, for example, substrate bonding pads 120 on the substrate 902 to facilitate passing of various power and signals to and from the die 100.

In some embodiments, other components can be mounted on or formed on the packaging substrate 902. For example, one or more surface mount devices (SMD) 910 and one or more matching networks 912 can be implemented. In some embodiments, the packaging substrate 902 can include a laminate substrate.

In some embodiments, the module 900 can also include one or more packaging structures to, for example, provide protection and facilitate easier handling of the module 900. Such a packaging structure can include overmold material 130 formed over the packaging substrate 902 and dimensioned to substantially encapsulate the various circuits and components thereon, for example, die 100.

A barrier 914 is formed between the lower surface 100A of the die 100 and the packaging substrate 902. The barrier 914 may include any of the dam or barrier structures described above, for example, embodiments of dam 125, dam 135, solder track 145, portion of a solder mask 145A, or solder track 145 in combination with track of bond pad material 140. The barrier may be formed wholly beneath the die 100 as illustrated in FIG. 9, or may extend outward from edges of the die as illustrated for dam 125 (FIG. 1), dam 135 (FIG. 3), and solder track 145 in combination with track of bond pad material 140 (FIG. 6). FIG. 9 illustrates a portion 914A of the barrier 914 disposed between the PA circuitry 904 and the coupler 906, however, this portion 914A may be omitted. Further, in some embodiments, the PA circuitry 904 and the coupler 906 may be formed on separate die both mounted on the packaging substrate 902.

Embodiments of the module 900 may be advantageously used in a variety of electronic devices. Examples of the electronic devices can include, but are not limited to, consumer electronic products, parts of the consumer electronic products, electronic test equipment, cellular communications infrastructure such as a base station, etc. Examples of the electronic devices can include, but are not limited to, a mobile phone such as a smart phone, a telephone, a television, a computer monitor, a computer, a modem, a hand held computer, a laptop computer, a tablet computer, an electronic book reader, a wearable computer such as a smart watch, a personal digital assistant (PDA), a microwave, a refrigerator, an automobile, a stereo system, a DVD player, a CD player, a digital music player such as an MP3 player, a radio, a camcorder, a camera, a digital camera, a portable memory chip, a health care monitoring device, a vehicular electronics system such as an automotive electronics system or an avionics electronic system, a washer, a dryer, a washer/dryer, a peripheral device, a wrist watch, a clock, etc. Further, the electronic devices can include unfinished products.

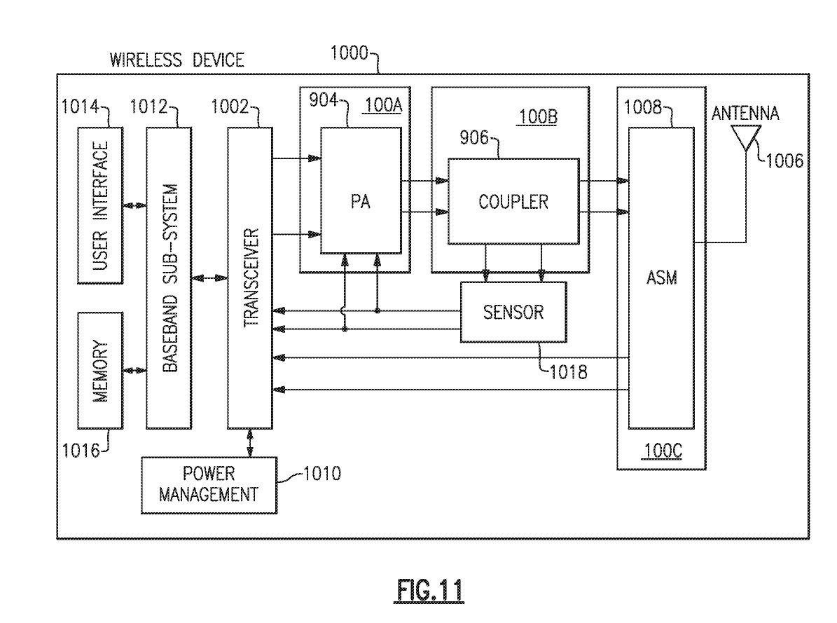

FIG. 10 is a block diagram of a wireless device 1000 including a flip-chip mounted die 100 according to certain embodiments. The wireless device 1000 can be a cellular phone, smart phone, tablet, modem, communication network or any other portable or non-portable device configured for voice and/or data communication. The wireless device 1000 includes an antenna 1006 that receives and transmits power signals and a coupler 906 that can use a transmitted signal for analysis purposes or to adjust subsequent transmissions. For example, the coupler 906 can measure a transmitted RF power signal from the power amplifier (PA) 904, which amplifies signals from a transceiver 1002. Coupler 906 and PA 904 may be included in a common die 100. The transceiver 1002 can be configured to receive and transmit signals in a known fashion. As will be appreciated by those skilled in the art, the power amplifier 904 can be a power amplifier module including one or more power amplifiers. The wireless device 1000 can further include a battery 1004 to provide operating power to the various electronic components in the wireless device.

FIG. 11 is a more detailed block diagram of an example of the wireless device 1000. As shown, the wireless device 1000 can receive and transmit signals from the antenna 1006. The transceiver 1002 is configured to generate signals for transmission and/or to process received signals. Signals generated for transmission are received by the power amplifier (PA) 904, which amplifies the generated signals from the transceiver 1002. In some embodiments, transmission and reception functionalities can be implemented in separate components (e.g. a transmit module and a receiving module), or be implemented in the same module. The antenna switch module 1008 can be configured to switch between different bands and/or modes, transmit and receive modes, etc. As is also shown in FIG. 11, the antenna 1006 both receives signals that are provided to the transceiver 1002 via the antenna switch module 1008 and also transmits signals from the wireless device 1000 via the transceiver 1002, the PA 904, the coupler 906, and the antenna switch module 1008. However, in other examples multiple antennas can be used.

The wireless device 1000 of FIG. 11 further includes a power management system 1010 that is connected to the transceiver 1002 that manages the power for the operation of the wireless device. The power management system 1010 can also control the operation of a baseband sub-system 1012 and other components of the wireless device 1000. The power management system 1010 provides power to the wireless device 1000 via the battery 1004 (FIG. 10) in a known manner, and includes one or more processors or controllers that can control the transmission of signals and can also configure the coupler 906 based upon the frequency of the signals being transmitted, for example.

In one embodiment, the baseband sub-system 1012 is connected to a user interface 1014 to facilitate various input and output of voice and/or data provided to and received from the user. The baseband sub-system 1012 can also be connected to memory 1016 that is configured to store data and/or instructions to facilitate the operation of the wireless device, and/or to provide storage of information for the user.

The power amplifier 904 can be used to amplify a wide variety of RF or other frequency-band transmission signals. For example, the power amplifier 904 can receive an enable signal that can be used to pulse the output of the power amplifier to aid in transmitting a wireless local area network (WLAN) signal or any other suitable pulsed signal. The power amplifier 904 can be configured to amplify any of a variety of types of signal, including, for example, a Global System for Mobile (GSM) signal, a code division multiple access (CDMA) signal, a W-CDMA signal, a Long Term Evolution (LTE) signal, or an EDGE signal. In certain embodiments, the power amplifier 904 and associated components including switches and the like can be fabricated on GaAs substrates using, for example, pHEMT or BiFET transistors, or on a silicon or SOI substrate using CMOS transistors.

Still referring to FIG. 11, the wireless device 1000 can also include a coupler 906 having one or more directional EM couplers for measuring transmitted power signals from the power amplifier 904 and for providing one or more coupled signals to a sensor module 1018. The sensor module 1018 can in turn send information to the transceiver 1002 and/or directly to the power amplifier 904 as feedback for making adjustments to regulate the power level of the power amplifier 904. In this way the coupler 906 can be used to boost/decrease the power of a transmission signal having a relatively low/high power. It will be appreciated, however, that the coupler 906 can be used in a variety of other implementations. In FIG. 11 the coupler 906, PA 904, and ASM 1008 are illustrated as being included in separate die 100A, 100B, 100C but in other embodiments two or more of these components and/or other components may be included in a common die 100.

In certain embodiments in which the wireless device 1000 is a mobile phone having a time division multiple access (TDMA) architecture, the coupler 906 can advantageously manage the amplification of an RF transmitted power signal from the power amplifier 904. In a mobile phone having a time division multiple access (TDMA) architecture, such as those found in Global System for Mobile Communications (GSM), code division multiple access (CDMA), and wideband code division multiple access (W-CDMA) systems, the power amplifier 904 can be used to shift power envelopes up and down within prescribed limits of power versus time. For instance, a particular mobile phone can be assigned a transmission time slot for a particular frequency channel. In this case the power amplifier 904 can be employed to aid in regulating the power level of one or more RF power signals over time, so as to prevent signal interference from transmission during an assigned receive time slot and to reduce power consumption. In such systems, the coupler 906 can be used to measure the power of a power amplifier output signal to aid in controlling the power amplifier 904, as discussed above. The implementation shown in FIG. 11 is exemplary and non-limiting. For example, the implementation of FIG. 11 illustrates the coupler 906 being used in conjunction with a transmission of an RF signal, however, it will be appreciated that coupler 906 can also be used with received RF or other signals as well.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Directional terms such as “above,” below,” “left,” “right,” etc. are used herein as a matter of convenience for referencing various surfaces and orientations of features disclosed herein. There directional terms do not imply that the aspects and embodiments disclosed herein are necessarily oriented in any particular orientation. Any dimensions provided in the above disclosure are meant as examples only and are not intended to be limiting.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while acts of the disclosed processes are presented in a given order, alternative embodiments may perform routines having acts performed in a different order, and some processes or acts may be deleted, moved, added, subdivided, combined, and/or modified. Each of these processes or acts may be implemented in a variety of different ways. Also, while processes or acts are at times shown as being performed in series, these processes or acts may instead be performed in parallel, or may be performed at different times.

The teachings of the invention provided herein can be applied to other systems, not necessarily the system described above. The elements and acts of the various embodiments described above can be combined to provide further embodiments.

Having thus described several aspects of at least one embodiment of this invention, it is to be appreciated various alterations, modifications, and improvements will readily occur to those skilled in the art. Any feature described in any embodiment may be included in or substituted for any feature of any other embodiment. Such alterations, modifications, and improvements are intended to be part of this disclosure, and are intended to be within the scope of the invention. Accordingly, the foregoing description and drawings are by way of example only.

What is claimed is:

1. A component of an electronic device comprising:
a semiconductor die flip-chip mounted directly on a printed circuit board; and
a barrier mechanically coupled to a portion of the die and the printed circuit board, the barrier defining a cavity between a surface of the die and the printed circuit board.

2. The component of claim 1 wherein the barrier comprises a polymeric material.

3. The component of claim 2 wherein the barrier comprises a thermoplastic material.

4. The component of claim 1 wherein the barrier comprises metal.

5. The component of claim 4 wherein the barrier comprises solder.

6. The component of claim 1 further comprising overmold material disposed over the die, the barrier, and a portion of the printed circuit board.

7. The component of claim 1 wherein the die is mounted in a cavity in the printed circuit board.

8. The component of claim 1 wherein the barrier is disposed about a periphery of the die.

9. The component of claim 1 wherein the die is electrically coupled to bonding pads disposed on the printed circuit board disposed within the cavity defined by the barrier via one of solder bumps and gold posts.

10. The component of claim 1 wherein the barrier hermetically seals the cavity.

11. The component of claim 1 wherein the cavity is free of underfill material.

12. The component of claim 1 wherein the die includes radio frequency (RF) components.

13. The component of claim 1 wherein the die includes a silicon-on-insulator (SOI) substrate.

14. The component of claim 1 included in an electronic device module.

15. The component of claim 14 wherein the electronic device module is a radio frequency (RF) device module.

16. The component of claim 15 included in an electronic device.

17. The component of claim 16 wherein the electronic device is an RF device.

18. A method of forming a component of an electronic device, the method comprising:
forming a semiconductor die;
flip-chip mounting the semiconductor die on a printed circuit board; and
forming a barrier mechanically coupled to a portion of the die and the printed circuit board, the barrier defining a cavity between a surface of the die and the printed circuit board.

19. The method of claim 18 further comprising mounting the component in an electronic device module.

20. The method of claim 20 further comprising mounting the electronic device module in an electronic device.
